(19) United States
(12) Patent Application Publication
(10) Pub. No.: US 2019/0014688 A1
(43) Pub. Date: Jan. 10, 2019

(54) VAPOR CHAMBER HEAT SPREADERS AND METHODS OF MANUFACTURNG THEREOF

(71) Applicant: PURDUE RESEARCH FOUNDATION, West Lafayette, IN (US)

(72) Inventors: Justin A. WEIBEL, West Lafayette, IN (US); Suresh V. GARIMELLA, West Lafayette, IN (US)

(73) Assignee: Purdue Research Foundation, West Lafayette (IN)

(21) Appl. No.: 16/060,622

(22) PCT Filed: Dec. 9, 2016
(86) PCT No.: PCT/US2016/065824

§ 371 Date: Jun. 8, 2018

Related U.S. Application Data
(60) Provisional application No. 62/266,330, filed on Dec. 11, 2015.

(51) Int. Cl. H05K 7/20; B23P 15/26

(52) U.S. Cl. CPC H05K 7/20336; H05K 7/20309; H05K 7/20936; B23P 15/26; H05K 7/20318

(57) ABSTRACT

Vapor chambers suitable for applications with power densities of one kW/cm² or greater over a heat input area of one cm² or greater and methods of manufacturing the same are provided. The vapor chambers include a housing having a thermally conductive substrate, a working fluid contained within the housing, a base layer formed of a porous thermally conductive material and located on and in thermal contact with the substrate, a cap layer formed of a porous thermally conductive material having through-holes formed therein defining vapor vents, and a plurality of conduits connecting the cap layer and the base layer with interstitial gaps therebetween. The conduits are capable of conveying the working fluid from the cap layer to the base layer. Heat entering the base layer causes the working fluid to evaporate from the base layer and the base layer is replenished with the working fluid through the conduits.

### BACKGROUND OF THE INVENTION

The present invention generally relates to heat dissipation for electronics applications. The invention particularly relates to vapor chamber heat spreaders having dual layer evaporators for improved heat dissipation over relatively large heat input areas.

The intensifying electrification of transportation systems and clean energy production technologies has dramatically increased the waste heat load that needs to be dissipated from high-density power electronic devices. This trend has pushed conventional air-cooling thermal management architectures to the limit; a reliance on conduction heat spreading from devices to the heat rejection surfaces incurs an overly large thermal resistance at power levels well below the inherent electrical power density limits of current and next generation devices. The integration of active liquid cooling architectures, such as high-performance single- and two-phase jet impingement or microchannel heat sinks, can alleviate these thermal limitations by eliminating the need for a direct low thermal resistance conduction pathway to the ultimate heat rejection surfaces. However, these systems require dedicated auxiliary components (for example, compressors/pumps, fluid connects, filters, etc.) which may be weak points for overall system reliability. In comparison, air cooling remains a proven and reliable approach for which heat transfer surfaces can be readily and accurately implemented.

Development of heat spreading technologies in next-generation systems are desired to enable air cooling of hotspots, that is, heat input areas with a relatively high temperature in comparison to its surroundings, for example, up to one kW/cm² and possibly more. Although solid heat-conduction spreaders are fundamentally limited to a linearly decreasing performance (increasing thermal resistance) with effective heat transfer distance, vapor chamber heat spreaders, also referred to herein as vapor chambers, implemented as a base of a solid heat-conduction spreader, such as a heat sink, offers promising solutions. FIG. 1 schematically represents an exemplary sealed vapor chamber heat spreader 10 filled with a liquid 24 of a working fluid that evaporates when locally heated at a heat input area (hotspot) 14 by a localized heat input 12. The resulting vapor 20 flows away from the hotspot 14 and condenses over a diffuse heat rejection surface 16. The resulting condensate 22 enters a wick structure 18 within the heat spreader 10. The wick structure 18 is generally a homogeneous porous flat/planar layer within the spreader 10. Within the wick structure 18, the condensate 22 coalesces to reform the working fluid liquid 24, which is transported back to the hotspot 14 via capillary action. Because the condensate 22 evaporates within the portion of the wick structure 18 located at the hotspot 14, the wick structure 18 may be referred to herein as an evaporator. This two-phase cycle allows passive heat spreading at a temperature gradient that can be orders of magnitude lower than conduction through solid materials.

While vapor chamber heat spreaders have been used extensively in electronics cooling applications, they have typically been utilized to transport heat over relatively long distances from low-heat-flux sources, where evaporation from a wick structure occurs in a predictable manner, that is, the total heat input is limited by capillary resupply to the evaporator at a relatively low surface superheat. The investigation of vapor chambers for high-heat-flux spreading applications has resulted in a paradigm shift where capillary limits are not encountered until a large surface superheat has been reached, and boiling occurs in the wick structure. The stochastic network of interconnected pores in sintered wick structures can continue to feed liquid to the heat source during boiling, and sustain a so-called “capillary-fed boiling” regime. FIG. 2 depicts a region of the vapor chamber heat spreader 10 of FIG. 1, and schematically represents the formation of a capillary-fed boiling regime as heat influx increases in the wick structure 18 from image (a) to image (c). As represented, the working fluid liquid 24 is heated and eventually caused to boil and evaporate due to heat conducted via an exterior wall 26 of the heat spreader 10. The thermal performance of vapor chamber heat spreaders at high-heat-flux operating conditions has been limited by the boiling heat transfer coefficient (which imposes the predominant thermal resistance) and capillary resupply under boiling conditions (which governs the maximum heat flux).

Capillary-fed boiling was first anecdotally described during measurements of thermal resistance across evaporator wick structures. Boiling was either directly observed or inferred from a sharp reduction in the thermal resistance upon incipience. While the single-phase capillary limit and boiling limit were treated as distinct phenomena before these studies, it was eventually determined that these limits are fundamentally interrelated and that boiling in the sintered wick structures incurred a large pressure drop that induced a premature capillary limit. Subsequent investigations specifically investigated capillary-fed boiling from high-heat-flux hotspots in simulated vapor chamber environments using sintered screen meshes, sintered powders, biporous sintered powders, and microposts. These investigations demonstrated that sintered wick structures could dissipate unprecedented heat fluxes of over 0.5 kW/cm² from small hotspots (0.04-0.25 cm²) if operated in a capillary-fed boiling regime. The inherent similarities between the vapor-formation regimes allowed generalized empirical correlation of the heat transfer coefficient by assuming that pseudo-vapor columns exist within the pore spaces during capillary-fed boiling. Parametric investigation of the wick thickness, porosity, and pore sizes revealed that improved thermal performance was obtained for morphologies that eased vapor removal from the wick structure and increased the area for interstitial phase change. Homogeneous wick structures are inherently restricted by a tradeoffbetween these characteristics. Therefore, multi-scale heterogeneous wicks have since been designed to either separate the liquid feeding and vapor extraction flow paths or distribute liquid to a thin, low-permeability layer. By providing vapor a high-permeability path to preferentially exit the wick structure, a reduced vapor-phase pressure drop lowers the surface superheat. A thin wick layer imposes an extremely low thermal resistance but has not been capable of sustaining liquid resupply. Thick sintered-particle arteries have demonstrated a four-fold increase in the maximum supported heat flux.

While heat fluxes of up to nearly one kW/cm² have been noted in the art under capillary-fed boiling conditions, there is a strong dependency of the maximum supported heat flux on the size of the heat input area. For example, FIG. 3 represents a plot of the heat flux supported by a 200 micrometer-thick sintered wick sample which showed a reduced heat flux from about 0.4 kW/cm² to about 0.1 kW/cm² due to an increase in the heat input area from 0.25 cm² to 1 cm² for a range of temperatures above the saturation temperature (Tₛₐₜ) of the working fluid, in other words, the boiling point of the working fluid. This data indicates that the two-phase conditions within the wick structure during capillary-fed boiling impose an excessively large pressure drop. While pressure drop data was not available during capillary-fed boiling, it is possible to correlate an approximate two-phase pressure drop based on the dryout heat flux for design purposes. As used herein, dryout refers to a situation wherein the liquid in the hotspot evaporates at a rate higher than it is replenished. In view of these limitations, existing wick structure designs are not scalable to large heat input areas, and all known demonstrations of high-heat-flux hotspot cooling of greater than 0.5 kW/cm² have been limited to heat input areas of less than 0.25 cm².

Thus, there is an ongoing desire for vapor chamber heat spreaders for applications with power densities of one kW/cm² over relatively large heat input areas, especially in circumstances where there may be a relatively low temperature differential (gradient) across the vapor chamber heat spreader, for example, temperature differentials of about 40 K and less.

### BRIEF DESCRIPTION OF THE INVENTION

The present invention provides vapor chamber heat spreaders suitable for applications with power densities of one kW/cm² or greater over heat input areas of at least 0.25 cm² or more, and preferably one cm² or greater.

According to one aspect of the invention, a vapor chamber heat spreader is provided that includes a housing having a thermally conductive substrate, a working fluid contained within the housing, a base layer formed of a porous thermally conductive material and located on and in thermal contact with the substrate, a cap layer formed of a porous thermally conductive material having through-holes formed therein defining vapor vents, and a plurality of conduits connecting the cap layer and the base layer with interstitial gaps between the conduits. The conduits are functionally operable to convey the working fluid from the cap layer to the base layer. The working fluid is capable of being evaporated by heat entering the base layer, condensing, and then flowing through the conduits to replenish the base layer.

According to another aspect of the invention, a method of making a vapor chamber heat spreader is provided that includes providing a thermally conductive substrate, depositing a thermally conductive powder onto the substrate, sintering the powder to form a porous thermally conductive material on the substrate, processing the material to form a base layer on the substrate and a plurality of conduits extending from the base layer with interstitial gaps therebetween, attaching a cap layer formed of a porous thermally conductive material to ends of the conduits oppositely disposed the base layer wherein the base layer, the conduits, and the cap layer define an evaporator, and sealing the evaporator and a working fluid in a housing, and the n sealing the evaporator and a working fluid in a housing. The cap layer has through-holes formed therein defining vapor vents that expose the interstitial gaps to a cavity on a side of the cap layer oppositely disposed from the conduits. The conduits are functionally operable to convey the working fluid from the cap layer to the base layer via capillary action. The working fluid is capable of being evaporated by heat entering the base layer, condensing, and then flowing through the conduits to replenish the base layer.

Technical aspects of the vapor chamber heat spreader and method described above preferably include the ability to provide reliable capillary-fed boiling at the highest temperature hotspot within the vapor chamber heat spreader for applications with power densities of one kW/cm² or greater over a heat input area of at least 0.25 cm², and preferably one cm² or greater.

Other aspects and advantages of this invention will be further appreciated from the following detailed description.

### BRIEF DESCRIPTION OF THE DRAWINGS

FIG. 1 is a perspective view representing a cross-section of a conventional vapor chamber heat spreader.

FIG. 2 schematically represents the formation of a capillary-fed boiling regime in a vapor chamber. Heat flux within an evaporator of the vapor chamber progressively increases from image (a) through image (c).

FIG. 3 is a graph comparing heat flux supported by a 200 micrometer-thick sintered wick structure for heat input areas of 0.25 cm² and 1 cm².

FIG. 4 is a perspective view representing a cross-section of a nonlimiting vapor chamber heat spreader having a two-layer evaporator, and further represents a detail of the cross-section.

FIGS. 5 through 7 schematically represent nonlimiting footprints of an array of posts and vapor vents in a two-layer evaporator.

FIG. 8 schematically represents a cross-section of a nonlimiting vapor chamber heat spreader having a two-layer evaporator. Various modeling parameters are indicated that were used in simulations leading to the present invention.

FIG. 9 is a graph representing a pressure drop ratio and temperature rise in the vapor chamber of FIG. 8 for various post diameters.

FIG. 10 includes images (a) through (g) that schematically represent steps in a nonlimiting process of fabricating a two-layer evaporator for a vapor chamber.

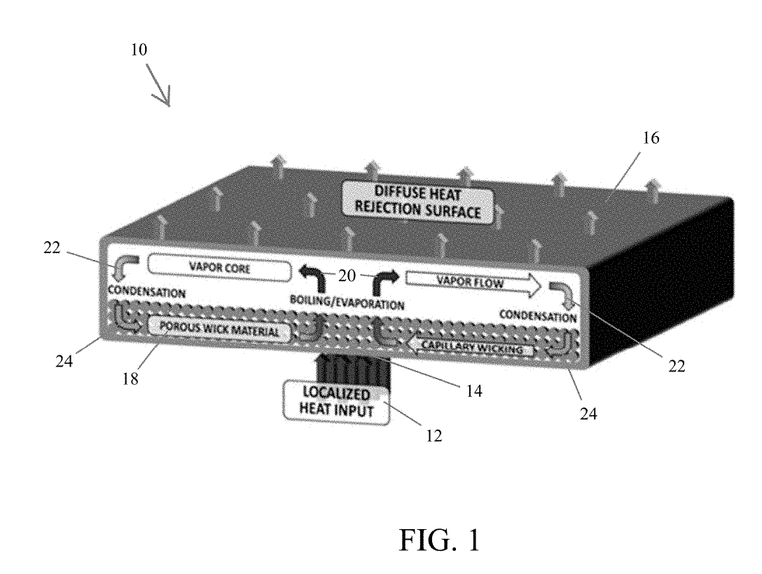

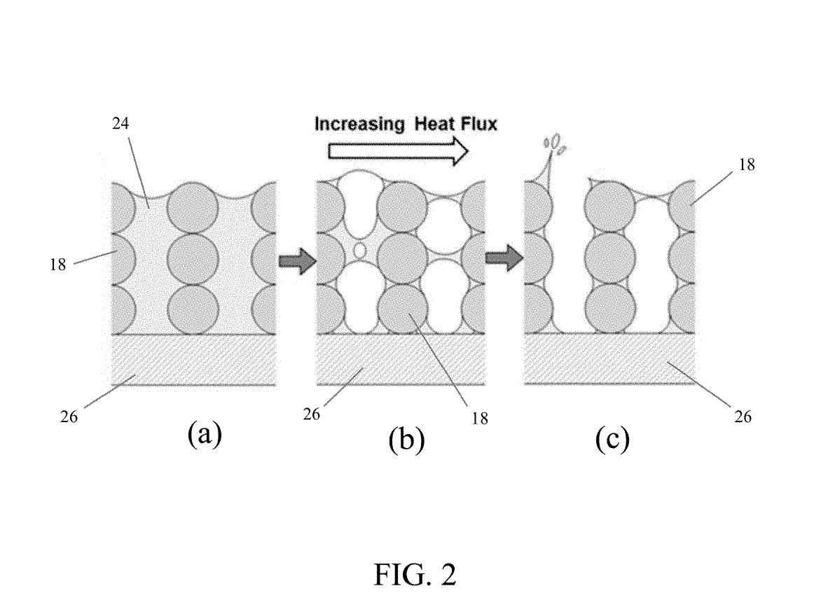

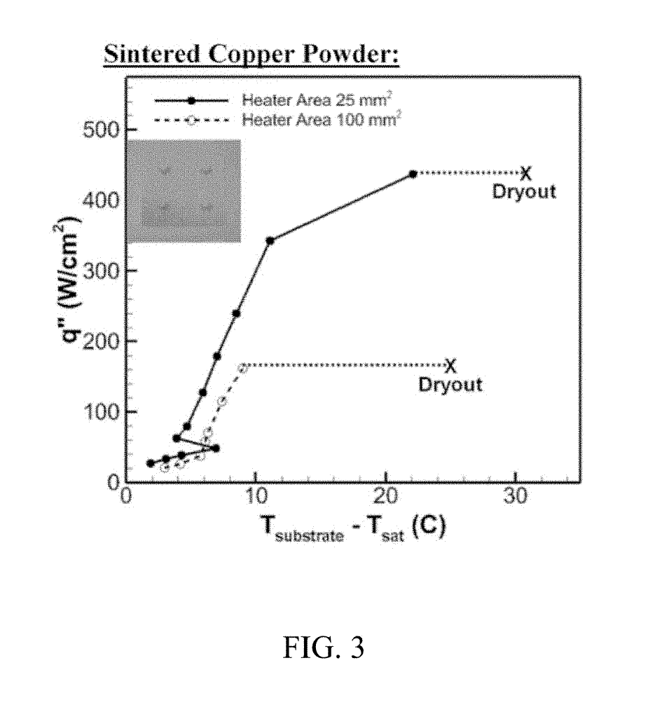

### DETAILED DESCRIPTION OF THE INVENTION

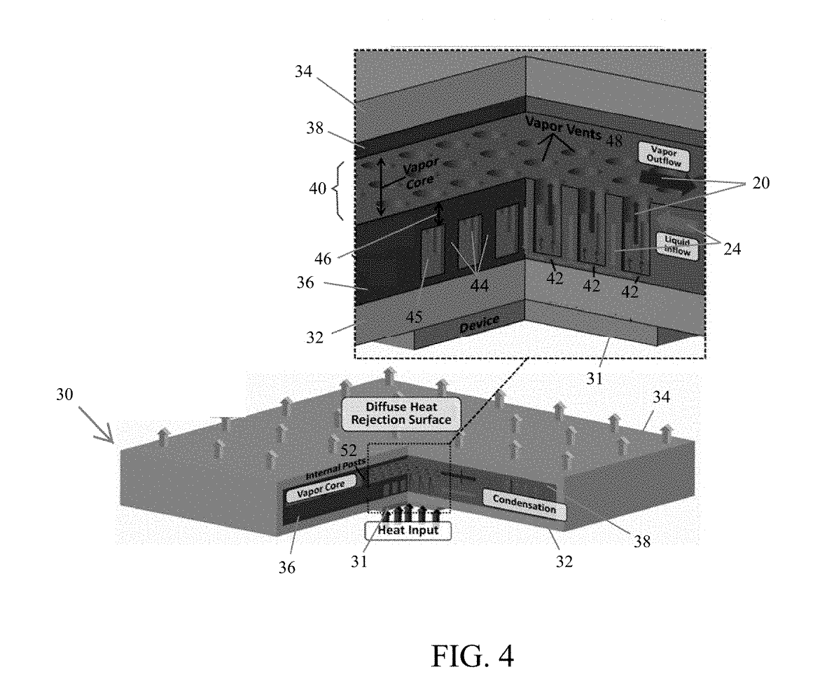

FIG. 4 schematically represents a nonlimiting vapor chamber heat spreader (hereinafter, vapor chamber) 30 suitable for applications involving, for example, high-power densities of one kW/cm² and above over a heat input area of at least 0.25 cm² or more, and preferably one cm² or greater. The vapor chamber 30 includes an enclosed housing having an evaporator-side wall 32 and an oppositely disposed condenser-side wall 34. The evaporator-side wall 32 is represented as receiving heat from a localized heat input device 31. Internally, the vapor chamber 30 includes a first porous wick structure defining a two-layer evaporator 36 in thermal contact (and preferably in physical contact) with the evaporator-side wall 32, such that heat received by the evaporator-side wall 32 from the localized heat input device 31 is conducted to the evaporator 36. The vapor chamber 30 further includes a second porous wick structure defining a condenser 38 in thermal contact (and preferably in physical contact) with the condenser-side wall 34. A cavity is present between and separating the evaporator 36 and condenser 38 and defines what will be referred to herein as a vapor core 40, so as to be in thermal contact (and preferably in physical contact) with the evaporator 36 and condenser 38. Internal posts (52 in FIG. 4), also referred to as liquid return posts, may be located throughout the vapor core 40 connecting the cap layer 46 to the condenser 38 to provide additional transport for liquid from the condenser 38 to the cap layer 46, and to provide mechanical support for the vapor chamber 30. The liquid return posts 52 may be porous wick structures.

The vapor chamber 30 will be described herein as utilizing water as a working fluid since the thermophysical properties of water are believed to be suitable for operating temperatures ranging from room temperature (about 20° C.) to about 200° C., which is an expected operating temperature range of current electronics devices. However, it is within the scope of the invention that the working fluid may a fluid other than water.

The evaporator 36 includes a base layer 42, an array of posts 44, and a cap layer 46. Interstitial gaps 45 are located around the posts 44 and between the base layer 42 and the cap layer 46. During use, heat from the heat input device 31 is conducted through the evaporator-side wall 32 to yield a heat input area (hotspot) in the base layer 42, generally corresponding to the surface area of the evaporator-side wall 32 contacted by the device 31. As the temperature increases, working fluid in the form of a liquid 24 in the base layer 42 may boil and evaporate as vapor 20. The vapor 20 rises and enters the vapor core 40 through vapor vents 48 present in the cap layer 46. As the vapor 20 flows to cooler areas within the vapor chamber 30, it condenses to reform the liquid 24 and enters the porous cap layer 46. Condensation and transport of the liquid 24 to the cap layer 46 may be promoted by the condenser 38. Due to capillary action, the liquid 24 is then transported through the cap layer 46, to and through the posts 44, and back to the base layer 42, preferably at a rate sufficient to maintain capillary-fed boiling at the hotspot in the base layer 42. The posts 44 may be referred to as “conduits” in light of their function of conducting or transporting the working fluid from the cap layer 46 to the base layer 42. The direction of flow of the working fluid, in both the vapor state 20 and liquid states (20 and 22), is represented in FIG. 4 with arrows.

The base layer 42 is preferably an ultra-thin, powder wick structure having a thickness on the order of about 200 micrometers, for example, about 25 to about 500 micrometers and more preferably about 50 to about 250 micrometers. The base layer 42 preferably provides a relatively low thermal resistance (about 0.03 Kcm²/W or below) under capillary-fed boiling (relatively high heat transfer coefficient). Preferably, the base layer 42 is sufficiently thin to promote reduction of the surface superheat temperature, for example, about 40 K or less.

Generally, relatively thin sintered powder base layers produce extremely low maximum supported heat flux due to the confined path of capillary-fed liquid supply. To address this limitation, the vertical liquid-feeding posts 44 are configured to distribute a capillary-fed supply of the liquid 24 across the hotspot from the cap layer 46 to prevent dryout within the base layer 42 at high-heat-flux operation. Although the posts 44 are represented as being vertical cylinders, it is within the scope of the invention that the posts 44 may be other shapes and have other orientations.

Alternative strategies for lateral liquid feeding within a vapor chamber, for example, with wedge-shaped or arterial wick structures, inherently reduce the available boiling surface area of the thin base layer 42 due to the need to provide an adequate cross sectional wicking area within a confined height. In the vapor chamber 30 represented in FIG. 4, the cap layer 46 decouples feeding pathways from the active boiling surface area, freeing the full footprint area of the hotspot (and a majority of the allotted vertical thickness of the evaporator 36) for capillary supply. (As used herein, the terms “available boiling surface area” and “active boiling surface area” refer to the footprint area of the base layer 42 that is not covered by the liquid-feeding posts 44.) While columnar liquid return pathways have been previously investigated, they generally involve connecting the evaporator directly to the condenser, forcing liquid supply across the entire thickness of the vapor chamber. In contrast, the two-layer evaporator 36 provides a comparatively shorter pathway promoting an increased rate of liquid resupply.

In addition to capturing and transporting liquid condensed from vapor, the cap layer 46 may provide a mechanism for proximate capture of droplet spray during intense capillary-fed boiling. This is beneficial as it has been observed that the maximum heat flux may be reduced due to liquid loss by this mechanism. It should be noted that while the proposed configuration may initially appear similar to other hybrid wicking structures that have a wick cap layer over the top of microposts, these designs have significantly different compositions and constructions, with the layers of the wick having significantly different forms and functions, wherein the interstitial gaps between the microposts are to remain filled with liquid and provide the primary high-permeability capillary pathways to a top evaporating cap layer. Such a cap layer does not provide any liquid feeding function, but is a very thin woven mesh attached to the top of the microposts to enhance the evaporation rate, and such microposts are solid and do not assist in capillary liquid supply. Consequently, the form, function, and intended operation of prior hybrid wicking structures drastically differ from the two-layer evaporator 36 proposed herein. An example of a prior hybrid wicking structure is reported in Oshman et al., “The Development of Polymer-Based Flat Heat Pipes,” Journal of Microelectromechanical Systems, Vol. 20, No. 2, pp. 410-417 (April 2011).

Despite the low thermal resistance of the base layer 42, any gradient in the saturated vapor pressure exiting the evaporator 36 can lead to a significant surface temperature rise. Therefore, the vapor vents 48 are incorporated into the cap layer 46 to provide a high-permeability pathway for vapor extraction from the interstitial gaps 45 between the posts 44. These gaps 45 will initially be flooded with liquid, but the menisci (that is, the upper surface of the liquid) will immediately recede upon marginal power input due to the negligible capillary pressure provided by the large-scale pores, leading to a regime of operation where liquid feeding and vapor venting pathways are completely separated, and pressure drop in the vapor phase in minimized.

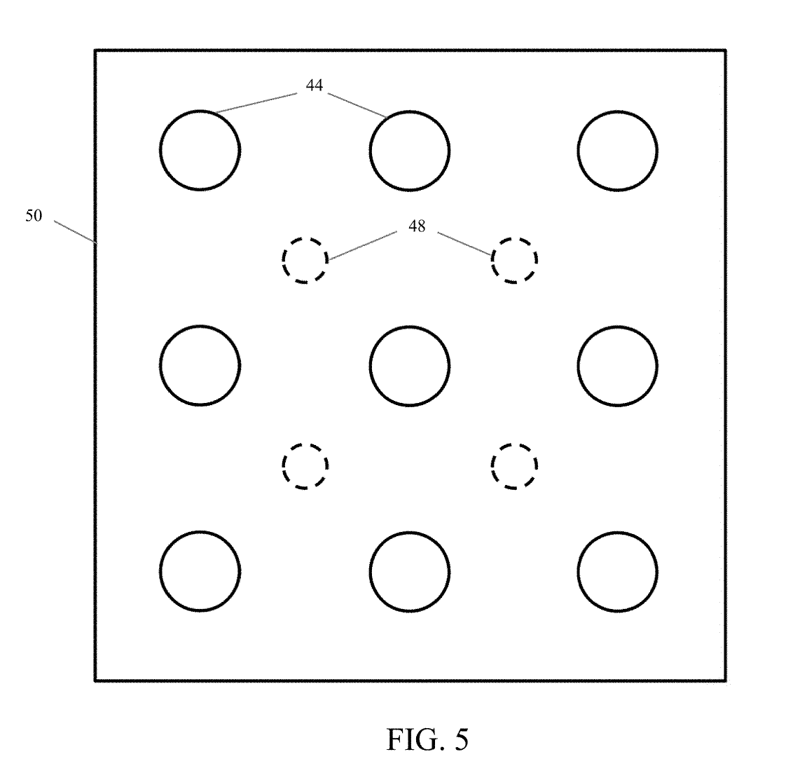

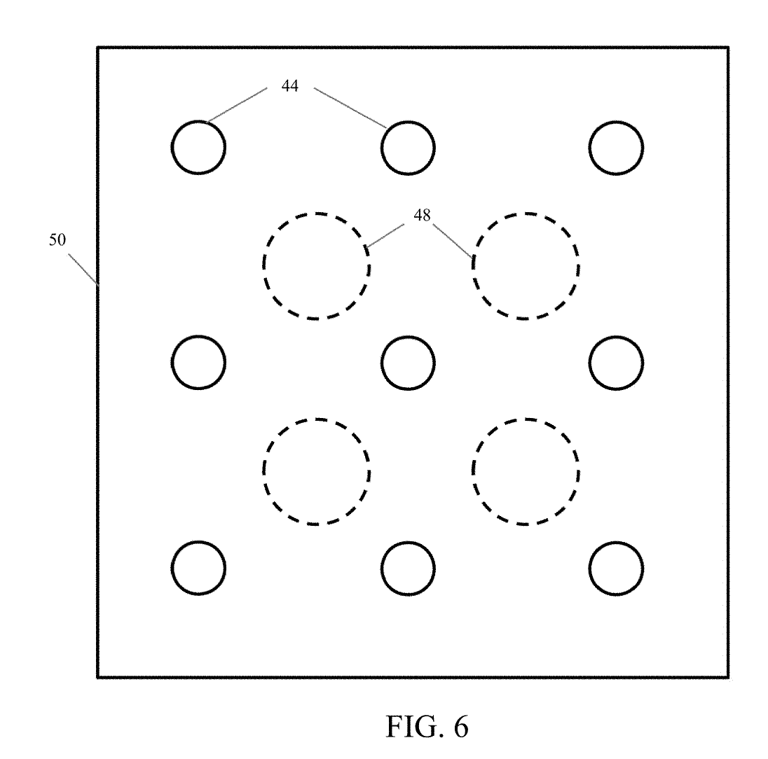

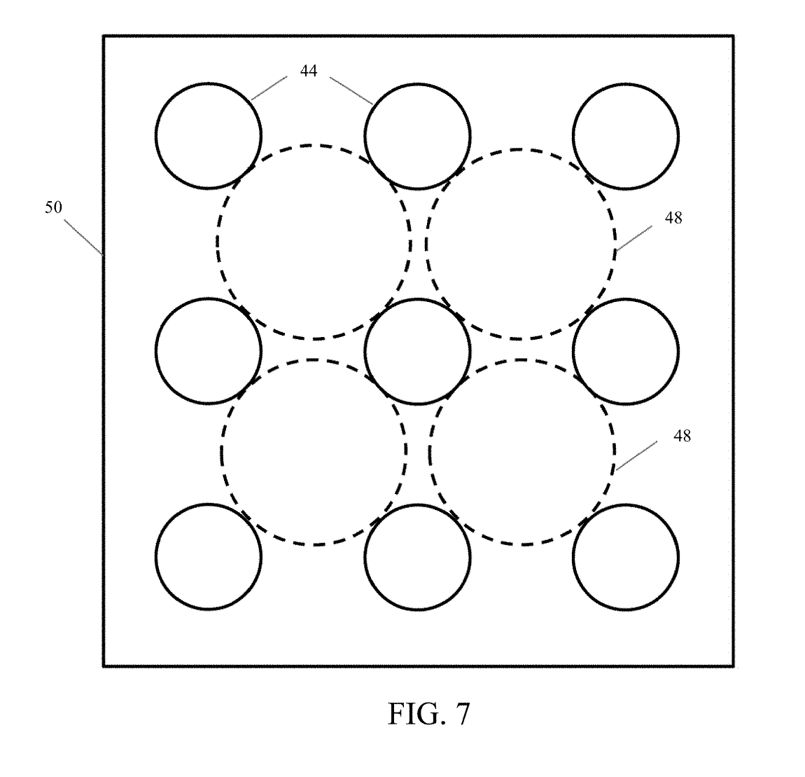

The liquid-feeding posts 44 and the vapor vents 48 may have various sizes, shapes, and dimensions. FIGS. 5 through 7 schematically represent nonlimiting footprints 50 of the evaporator 36 depicting arrays of cylindrical posts 44 and circular vapor vents 48 of various relative sizes. Specifically, FIG. 5 represents each post 44 as having a diameter that is larger than the diameter of each vapor vent 48, and more particularly all of the posts 44 as having approximately the same diameter, all of the vapor vents 48 as having approximately the same diameter, and the diameter of the posts 44 is larger than the diameter of the vapor vents 48. FIG. 6 represents each post 44 as having a diameter that is smaller than the diameter of each vapor vent 48, and more particularly all of the posts 44 as having approximately the same diameter, all of the vapor vents 48 as having approximately the same diameter, and the diameter of the posts 44 is smaller than the diameter of the vapor vents 48. FIG. 7 represents a scenario similar to FIG. 6, but with the vapor vents 48 having diameters sufficiently large to be adjacent or contiguous with the perimeters of the posts 44. Although the posts 44 and vapor vents 48 are represented as having uniform dimensions and oriented in a uniform staggered and alternating array, it is within the scope of the invention that the posts 44 and vapor vents 48 may having varying dimensions throughout the array, and may be oriented in patterns other than those depicted.

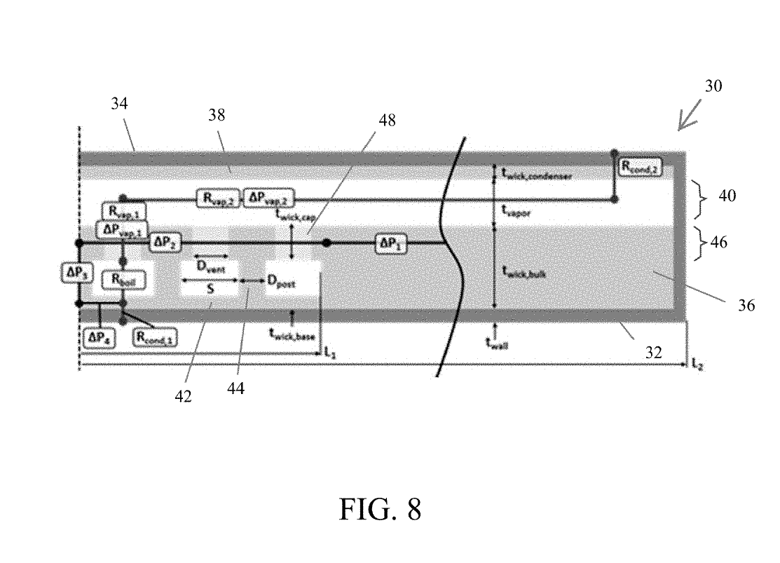

FIG. 4 represents the vapor vents 48 as having a diameter that is about equal to a dimension spanning the interstitial gaps 45 directly between adjacent posts 44. Alternatively, FIGS. 8 and 11 represent vapor vents 48 that have diameters that are smaller than the dimension spanning the interstitial gaps 45 directly between adjacent posts 44. As represented, this results in portions of the cap layer 46 extending over the top of the interstitial gaps 45 adjacent to the posts 44 to effectively yield a step as viewed from the angle represented in FIGS. 8 and 11. Decreasing the size of the vapor vents 48 inherently increases the surface area of the cap layer 46 located over the interstitial gaps 45, which is believed to promote the aforementioned mechanism for proximate capture of droplet spray during intense capillary-fed boiling.

The vapor chamber 30 and its components may be formed of various materials. The housing of the vapor chamber 30 is preferably a highly thermally conductive metal or alloy, such as but not limited to copper, which is suitable for conducting heat from the heat input device 31. The evaporator 32 and the condenser 38 are porous wick structures formed of hydrophilic (if water is the working fluid) and preferably conductive materials, a nonlimiting example being a sintered copper powder, that preferably comprising superhydrophilic nanostructures. As used herein, the wetting of a liquid with a surface of a solid material will be described in relation to a contact angle at which the liquid-vapor interface meets the solid-liquid interface. A wettable surface (for example, hydrophilic if water is the working fluid) is any surface with a contact angle of less than 90° (low contact angle) which indicates that wetting of the surface is very favorable, and a liquid will likely spread over the surface and in the case of a porous material, may spread into the material. A nonwettable surface (for example, hydrophobic if water is the working fluid) is any surface with a contact angle of greater than 90° (high contact angle) which indicates that wetting of the surface is unfavorable, so a liquid will likely minimize contact with the surface and form a compact liquid droplet on the surface. A superphilic surface (for example, superhydrophilic if water is the working fluid) refers to a surface on which a liquid will uniformly spread such that it forms a thin conformal liquid layer rather than a droplet with a measurable contact angle. Therefore, the above-mentioned superhydrophilic nanostructures are structures that either have superhydrophilic surfaces, or in combination form a superhydrophilic surface.

While copper is intrinsically hydrophilic, careful control of the environmental conditions (viz., a vacuum or reducing atmosphere) is preferred in vapor chamber fabrication and processing steps in order to maintain repeatable wetting characteristics. To alleviate these process control restrictions, the wick structures can be functionalized to maintain or enhance their intrinsic wettability. While a variety of approaches have been proposed that impart or promote wettability by producing or processing the wick structure to have textured or nanostructured surfaces (i.e., comprising surfaces with nanostructure features), these techniques often require line-of-sight processes for catalyst deposition or nanowire growth. Alternatively, thermal or solution-immersion chemical processes can be used to grow conformal layers of stable copper oxide. Thermally grown Cu₂O can provide controlled hydrophilicity, but the relatively smooth layer does not provide geometric enhancement of wettability. CuO nanostructures grown chemically in alkali solutions can yield excellent superhydrophilic wetting behavior. Superhydrophilic copper oxide nanostructures grown chemically on the surface renders the sintered copper surface superhydrophilic and the thin oxide layer has a negligible thermal resistance.

A feasibility analysis was performed to demonstrate that the vapor chamber 30 is capable of yielding at least about one kW/cm² heat dissipation over at least about one cm² area for which the two-layer evaporator 36 can sustain capillary liquid supply to a hotspot, and the temperature of the evaporator 36 remains below a target value, for example, a temperature rise of 40 K or less. The schematic diagram shown in FIG. 8 represents primary thermal and hydraulic resistances within the system. Liquid needs to overcome viscous pressure drop across the porous wick structure when returning from the periphery to the evaporator 36 (ΔP₁), across the cap layer 46 (ΔP₂) and posts 44 (ΔP₃), and across the two-phase pressure drop in the base layer 42 during capillary-fed boiling (ΔP₄). The increase in the temperature of the evaporator 36 was governed by conduction resistances (R_{cond,1+2}), the resistance associated with capillary-fed boiling from the base layer 42 (R_{boil}), and the saturation temperature gradient due to flow through the cap layer 46 (R_{vap,1}) and to the periphery (R_{vap,2}). These latter saturation temperature gradients are induced by a pressure drop in the vapor phase (ΔP_{vap,1+2}) that can also be accounted for in the total pressure drop.

In order to study the performance of the proposed two-layer evaporator 36, a reduced-order model was developed. The model included a two-layer evaporator containing a square array of the liquid feeding posts 44 over a heat input area (hotspot). The model assumed that the liquid-phase pressure drop returning from peripheral regions was negligible due to the bulk wick structure thickness in this region and the presence of liquid return posts (not shown) throughout the vapor core 40 (which are typically included in vapor chambers for mechanical support). The pressure drop in the cap layer (ΔP₂) was calculated assuming axisymmetric inward flow in a representative disk of porous media having the same footprint area as the evaporator 36, with uniform mass loss to the liquid-feeding posts 44. The effective thickness of this disk was reduced based on the percentage area of vapor vents 48. Pressure drop across the liquid-feeding posts (ΔP₃) was calculated based on uniform one-dimensional flow through an equivalent cross-sectional area. There are no available methods for mechanistic prediction of the two-phase pressure drop in the base layer 42 (ΔP₄), therefore this pressure drop was estimated by extrapolating previous empirical data for which the pressure gradient was correlated to the superficial vapor velocity exiting the wick structure at a given thickness of 200 micrometers.

Thermal resistances for the model were calculated assuming uniform heat rejection through the surface of the condenser 38. Conduction resistances (R_{cond,1+2}) included the vapor chamber walls and saturated condenser 38. While semi-empirical models can be used to correlate capillary-fed boiling thermal resistances (R_{boii}), the model instead assumed a fixed value of 0.03 Kcm²/W based on experimental observations for a 200 micrometer-thick wick structure. The pressure drop (ΔP_{vap,1}) across the vapor vents 48 was calculated assuming Hagen-Poiseuille flow (neglecting minor losses). The pressure drop in the vapor core 40 (ΔP_{vap,2}) was calculated assuming axisymmetric viscous outward flow in an equivalent disc-shaped region. The associated vapor saturation temperature gradients (R_{vap,1+2}) were calculated using the Clausius-Clapeyron relation.

A baseline case was chosen to represent the performance targets (Q=1 kW, tₜₒₜₐₗ=3 mm, A₁=1 cm², A₂=100 cm²). All thermophysical fluid properties were evaluated at a saturation temperature of 100° C. All wick regions were assumed to be composed of 45 to 75 micrometer-diameter sintered copper powder due to the availability of property data (k_{eff}=56 W/mK, K=2.5×10⁻¹¹ m², P_{cap}=4σ/Dₚ where Dₚ=74 micrometers) obtained via microtomography based simulations of actual structures. Several geometric parameters were chosen based on convention (t_{wick,condenser}=t_{wall}=200 micrometers) and the availability of empirical data (t_{wick,base}=200 micrometers).

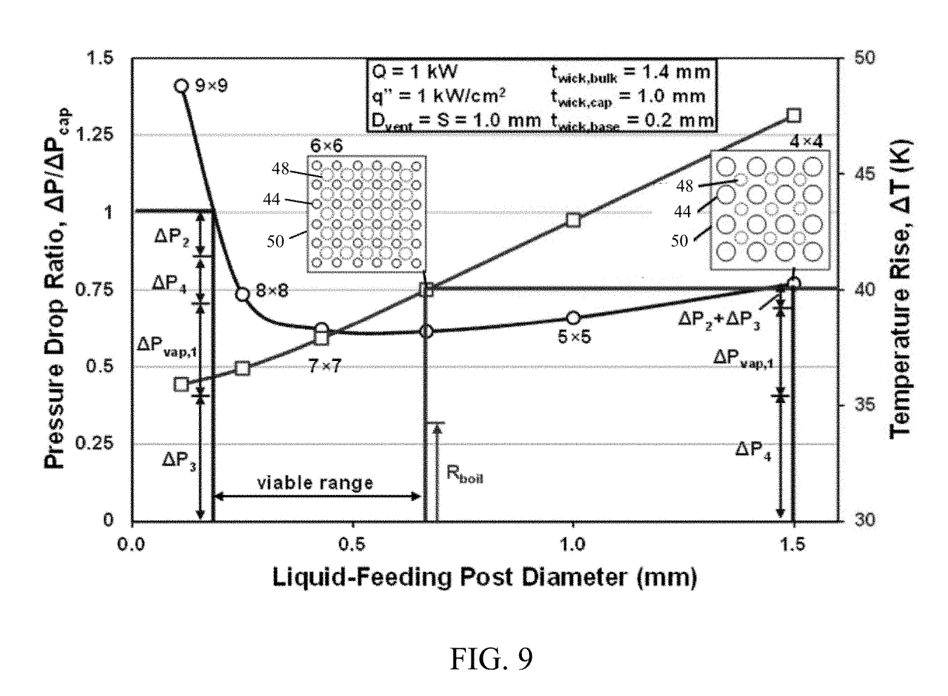

A thickness of 1 mm was used for the vapor core 40, a bulk thickness of 1.4 mm was used for the evaporator 36, and a thickness of 1 mm was used for the cap layer 46 (i.e., 400 micrometer-tall liquid-feed posts 44). These dimensions were chosen based on an evaluation of the model for various possible geometric configurations and estimated manufacturing constraints. A parametric evaluation of the liquid-feeding post array was performed assuming that the post spacing (S) and vapor vent diameter (Dᵥₑₙₜ) were equal. The results of this evaluation are represented for various post diameters (Dₚₒₛₜ) at a constant spacing of S=1 mm in FIG. 9. The pressure drop ratio data points are indicated with circles and the temperature rise data points are represented with squares. The contributions of individual hydraulic and thermal resistances to the overall values are shown at selected design points. In the model, the predominant thermal resistance was capillary-fed boiling across the base layer 42 (R_{boil}). Therefore, an increase in liquid-feeding post diameter (Dₚₒₛₜ), for example, from the 6×6 array to the 4×4 array depicted in FIG. 9, yielded constriction of the input heat flux to a smaller footprint area which resulted in a temperature rise. While the overall pressure drop had a number of contributing factors, a large gradient across the liquid-feeding posts 44 (P3) became limiting at small diameters.

FIG. 9 indicates a window of potential geometric configurations for which the modeled two-layer evaporator was viable (bounded by a capillary supply limit at small post diameters (for example, the 9×9 array reported in FIG. 9) and an application-specific over-temperature limit at large post diameters (for example, the 4×4 array reported in FIG. 9)). In FIG. 9, the capillary supply and over-temperature limits are indicated by the “viable range” end points, wherein the left end point of this range is based on the capillary limit where the pressure drop is equal to 1, and the right end point of this range is set at an over-temperature limit that was established for the particular application. This model simulation provided insight into the parametric trends and feature sizes required. For example, a configuration with a 6×6 array of 0.66 mm-diameter liquid-feeding posts 44 may sustain the target heat flux with some factor of safety on the pressure drop (shown as an inset). Variation of the post spacing (not shown) suggested that lowered pressure drops and surface temperatures are possible with smaller feature sizes. Though not wishing to be held to any particular combinations of geometric feature sizes, the simulation suggested that the following feature sizes are desirable or required: sintered particle sizes of about 10 to about 250 micrometers (all sintered features are preferably at least twice the size of the particles from which they are formed); sintered porosities of about 30 to about 70%; liquid-feeding post sizes of up to about 500 micrometers; liquid-feeding post heights of about 100 to about 1000 micrometers; interstitial gaps of about 100 to about 1000 micrometers; cap layer thicknesses of 500 micrometers or more; and vapor vent diameters of 100 micrometers or more.

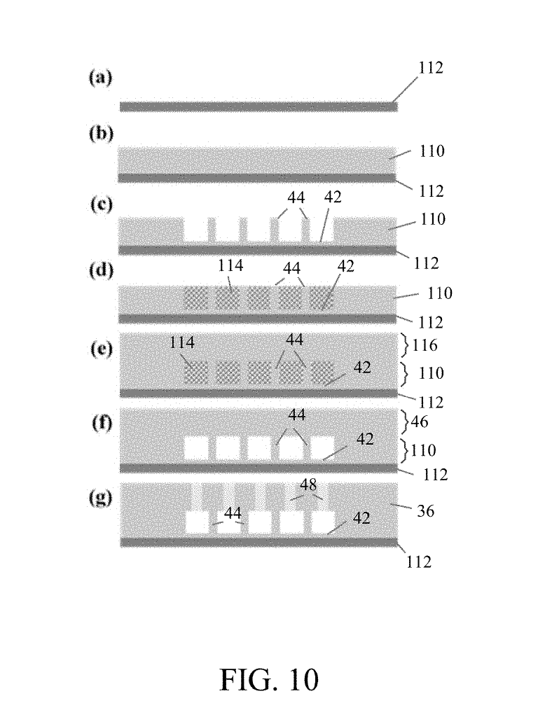

FIG. 10 schematically represents a nonlimiting process suitable for fabrication of a vapor chamber such as that represented in FIG. 4. Initially, a uniform sintered wick layer 110 is fabricated (images a and b). For example, a loose copper powder may be poured into a graphite mold that preferably allows leveling to a desired thickness. The powder may be sintered to a copper substrate 112 at elevated temperatures in a furnace with a reducing or inert atmosphere. The porosity of the wick layer 110 can be controlled by the sintering time and temperature as desired. The fidelity of the wick layer 110 can be evaluated with X-ray microtomography scanning of excised samples of material. The base layer 42 and posts 44 can be formed (image c) by removing portions of the wick layer 110 to a desired depth, for example by ablating, machining, etching, etc.

To attach the cap layer 46, the exposed recesses in the wick layer 110 can be backfilled with a temporary filler material 114 (image d), such as but not limited to carbonate particles, before applying a second layer of loose copper powder thereover 116 (image e). During a lost-carbonate sintering (LCS) process, the carbonate particles decompose at the elevated sintering temperatures, leaving behind the features formed by the sintered copper particles to form the cap layer 46 (image f). Vapor vents 48 can then be formed in the cap layer 46 (image g).

Optionally, surface modifiers, such as copper oxide nanostructures, can be coated onto the as-fabricated evaporator 36 (image g) to impart wetting hydrophilic, and preferably superhydrophilic, behavior. This can be achieved with a chemical solution-immersion process that subjects the samples to an alkali solution.

For the material removal steps of images (c) and (g) of FIG. 10, a laser-etching technique can be used for subtractive fabrication of the posts 44 and vapor vents 48. Unlike conventional machining approaches that may fragment the porous layer, this non-contact approach may preserve the properties of the sintered layer. A suitable but nonlimiting laser-cutting system is produced by Universal Laser and commercially available under the trademark PLS6MW Multi-Wavelength Laser Platform, and is capable of cutting feature sizes with microscale lateral resolution (tens of microns).

An alternative ablation method is electrical discharge machining (EDM), a common industrial process where the electrode tool is held at a voltage differential from the substrate to be machined and dielectric breakdown causes material to be ablated from the substrate and electrode. Other conventional machining processes can also be explored. However, it is preferred that the properties of the sintered coating are at least partially if not fully maintained after material removal is complete.

The feasibility calculations suggested that millimeter-scale features can achieve desirable performance targets of 1 kW/cm2 heat flux over a 1 cm² surface area with a temperature rise of 40 K. For images (d) through (f) of FIG. 10, since the cap layer 46 only requires hydraulic coupling to the liquid-feeding posts 44 (i.e., does not require thermal contact), a separate wick structure (such as a screen mesh) can be simply pressed against the underlying posts 44, rather than formed in situ. Similarly, the base layer 42 may be formed of a separate wick structure, such as a screen mesh.

Conventional fabrication methods (e.g., using a mold to sinter particles onto solid posts) impose fabrication constraints that limit feature size and reduces the percentage of cross-sectional area available for liquid feeding, ultimately negating any performance improvement over lateral feeding approaches. The fabrication process described herein allows for improved flexibility of the liquid-feeding post height and diameter to yield improved performance.

In view of the above, the evaporator 36 is a scalable, two-layer structure that provides low thermal resistance operation while maintaining adequate passive liquid feeding by capillary action over relatively large heat input areas and relatively high power densities, as nonlimiting examples, heat input areas of 1 cm² or greater and power densities of 1 kW/cm² or greater.

While the invention has been described in terms of specific or particular embodiments, it should be apparent that alternatives could be adopted by one skilled in the art. For example, the vapor chamber 30 and its components could differ in appearance and construction from the embodiments described herein and shown in the drawings, functions of certain components of the vapor chamber 30 could be performed by components of different construction but capable of a similar (though not necessarily equivalent) function, and appropriate materials could be substituted for those noted. In addition, the invention encompasses additional or alternative embodiments in which one or more features or aspects of different disclosed embodiments may be combined. Accordingly, it should be understood that the invention is not necessarily limited to any embodiment described herein or illustrated in the drawings. It should also be understood that the phraseology and terminology employed above are for the purpose of describing the disclosed embodiments and investigations, and do not necessarily serve as limitations to the scope of the invention. Therefore, the scope of the invention is to be limited only by the following claims.

1. A vapor chamber heat spreader (30) comprising:
a housing having a thermally conductive substrate (32);
a working fluid contained within the housing;
a base layer (42) formed of a porous thermally conductive material and located on and in thermal contact with the substrate (32);
a cap layer (46) formed of a porous thermally conductive material having through-holes defined therein defining vapor vents (48); and
a plurality of conduits (44) connecting the cap layer (46) and the base layer (42), the conduits (44) having interstitial gaps (45) therebetween, the conduits (44) being functionally operable to convey the working fluid from the cap layer (46) to the base layer (42);
wherein the working fluid is capable of being evaporated by heat entering the base layer (42), condensing, and then flowing through the conduits (44) to replenish the base layer (42).

2. The vapor chamber heat spreader (30) of claim 1, wherein the base layer (42) is formed of sintered powder.

3. The vapor chamber heat spreader (30) of claim 1, wherein the cap layer (46) is formed of sintered powder.

4. The vapor chamber heat spreader (30) of claim 1, wherein the conduits (44) are formed of sintered powder.

5. The vapor chamber heat spreader (30) of claim 1, wherein the working fluid is water.

6. The vapor chamber heat spreader (30) of claim 1, wherein the conduits (44) are cylindrical posts extending between the base layer (42) and the cap layer (46).

7. The vapor chamber heat spreader (30) of claim 6, wherein the posts define a predetermined array and the interstitial gaps (45) are located between the base layer (42) and the cap layer (46).

8. The vapor chamber heat spreader (30) of claim 1, further comprising:
a thermally conductive wall (34) oppositely disposed from the thermally conductive substrate (32);
a condenser (38) formed of a porous thermally conductive material and located on and in thermal contact with the wall (34); and
a cavity defining a vapor core (40) separating the condenser (38) and the cap layer (46).

9. The vapor chamber heat spreader (30) of claim 1, wherein at least some of the conduits (44) individually have a cross-sectional area that is less than a cross-sectional area of at least some of the vapor vents (48).

10. The vapor chamber heat spreader (30) of claim 1, wherein the conduits (44) have a cross-sectional area that is sufficiently large to resupply the working fluid to the base layer (42) at a rate that is at least equal to the rate of evaporation of the working fluid from the base layer (42), and that is sufficiently small to avoid an over-temperature limit of 40 K within the conduits (44) when exposed to a power density of at least one kW/cm2 in a heat input area of at least one cm2.

11. The vapor chamber heat spreader (30) of claim 1, wherein the cap layer (46) and conduits (44) are functionally operable to transport the working fluid to the base layer (42) via a capillary action.

12. The vapor chamber heat spreader (30) of claim 11, wherein the evaporation of the working fluid in the base layer (42) is due to capillary-fed boiling.

13. The vapor chamber heat spreader (30) of claim 12, wherein the cap layer (46) promotes proximate capture of droplet spray during intense capillary-fed boiling.

14. A method of making a vapor chamber heat spreader (30), the method comprising:
providing a thermally conductive substrate (32);
forming a porous thermally conductive material on the substrate (32);
processing the material to form a base layer (42) on the substrate (32) and a plurality of conduits (44) extending from the base layer (42) with interstitial gaps (45) therebetween;
attaching a cap layer (46) formed of a porous thermally conductive material to ends of the conduits (44) oppositely disposed the base layer (42), the cap layer (46) having through-holes therein defining vapor vents (48) that expose the interstitial gaps (45) to a cavity (40) on a side of the cap layer (46) oppositely disposed from the conduits (44), the conduits (44) being functionally operable to convey the working fluid from the cap layer (46) to the base layer (42) via capillary action, the base layer (42), the conduits (44), and the cap layer (46) defining an evaporator (36); and
sealing the evaporator (36) and a working fluid in a housing;
wherein the working fluid is capable of being evaporated by heat entering the base layer (42), condensing, and then flowing through the conduits (44) to replenish the base layer (42).

15. The method of claim 14, further comprising forming the vapor vents (48) in the cap layer (46) after attaching the cap layer (46) to the conduits (44).
